(19) United States
(12) Patent Application Publication
(10) Pub. No.: US 2008/0123448 A1
(43) Pub. Date: May 29, 2008

(54) Memory device architecture and method for high-speed bitline pre-charging

(76) Inventors: Marco Goetz, Radebeul (DE); Zeev Cohen, Zichron-Yaakov (IL)

Correspondence Address: SLATER & MATSIL LLP, 17950 PRESTON ROAD, SUITE 1000, DALLAS, TX, 75252, US

(21) Appl. No.: 11/593,991

(22) Filed: Nov. 7, 2006

(51) Int. Cl. G11C 7/12

(52) U.S. Cl. 365/203

(57) ABSTRACT

A memory device is presented that includes a plurality of memory cells coupled to a bitline, and two or more pre-charging circuits coupled to the bitline. Each of the pre-charging circuits is operable to supply a pre-charge voltage to the bitline, thereby reducing the effective R-C time constant of the bitline compared with the conventional approach in which only a single pre-charging circuit is employed.

### TECHNICAL FIELD

The present invention relates to memory devices and in particular to a memory device architecture and method for performing high-speed bitline pre-charging operations.

### BACKGROUND

The performance of a memory device is in large part judged by how fast data can be read from or written to the memory. Data reading and writing operations themselves involve many processes, one of which is the pre-charging of a selected memory cell's bitline, whereby a common bitline, which is coupled to a desired cell, is pre-charged to a predefined voltage in preparation for a data reading or writing operation. It is, therefore, important that bitline pre-charging operations be performed quickly in order to expedite data reading and writing operations.

FIG. 1A illustrates a memory device employing bitline pre-charging circuitry. As shown, the memory device includes complementary bitlines 112 and 114 between which are coupled memory cells MC₁₋ₙ, shown as field effect transistors. The gate terminal of each of the MC₁₋ₙ devices is coupled to respective wordlines WL₁₋ₙ in a conventional bitline/wordline matrix. The memory may be any type of memory, for example, those used in volatile memory structures, such as static or dynamic random access memory devices, or non-volatile memory (read only, as well as programmable) structures such as electrically erasable programmable read only memories (EEPROMs), flash memories and the like.

Complementary bitlines 112 and 114 are pre-charged to a predefined voltage by means of pre-charge circuits 122 and 124, respectively. Once pre-charged, a writing voltage is supplied to the wordline WL of the selected memory cell, thereby activating the selected memory cell for a reading or writing operation.

As memory devices 100 increase in density and capacity, the number of memory cells disposed along bitlines 112 and 114 will increase, and accordingly the length of the bitlines grows longer in order to accommodate the larger number of memory cells. As the length of bitlines 112 and 114 increases, a delay effect is produced between the first and last memory cells MC₁ and MCₙ, the magnitude of the delay being a function of the length of the bitlines 112 and 114, and the line's loading conditions.

FIG. 1B illustrates a portion of a memory device showing a bitline equivalent circuit and a pre-charging circuit, wherein each of the memory cells MC₁₋ₙ are modeled as equivalent R-C pi-(π) circuit structures, the shunt capacitances, for example, representing the FET's effective gate and drain capacitances to ground, and the series resistance representing the intrinsic resistivity of the bitline 114 per unit length. Each memory cell can be alternatively modeled as a T-structure.

The effect of the series resistors and the shunt capacitors combine, such that the bitline 114 develops a delay between MC₁ and MCₙ, the delay being given by the equation:

$$Delay = {\sum }_{n}^{i = 1} \frac{1}{{R}_{i} {C}_{i}}$$

As the memory's bitlines grow longer to accommodate a greater number of memory cells, the delay effect produced thereby increases. As a result, a substantial time delay arises between the time at which the pre-charging circuit 124 is activated and the time at which the pre-charge voltage develops at the desired memory cell, the delay being greatest for the most distally-located memory cell MCI. This delay must be factored into the total timing budget, and typically the longest delay will set the duration of the bitline pre-charge operation, as all pre-charging operations are only guaranteed if this delay is taken into account. As a result, the longest bitline pre-charge duration limits the overall speed of the memory device, especially in larger memory arrays.

What is therefore needed is a new memory device architecture and method for providing high-speed bitline pre-charging.

### SUMMARY OF THE INVENTION

The present invention provides an improved memory device architecture and method for providing high-speed bitline pre-charging operations to overcome the delay effects of longer bitlines employed in high density memories. Faster bitline pre-charging enables faster memory accessing and faster programming operations.

In one representative embodiment of the invention, a memory device is presented, which includes a plurality of memory cells coupled to a bitline, and two or more pre-charging circuits coupled to the bitline. Each of the pre-charging circuits is operable to supply a pre-charge voltage to the bitline, thereby reducing the effective R-C time constant of the bitline compared with the conventional approach in which only a single pre-charging circuit is employed.

These and other features of the invention will be better understood when taken in view of the following drawings and detailed description.

### BRIEF DESCRIPTION OF THE DRAWINGS

For a more complete understanding of the present invention, and the advantages thereof, reference is now made to the following descriptions taken in conjunction with the accompanying drawing, in which:

FIG. 1A illustrates a memory device employing bitline pre-charging circuitry;

FIG. 1B illustrates a portion of a memory device showing a bitline equivalent circuit and a pre-charging circuit of FIG. 1A;

FIG. 2 illustrates a portion of a memory device showing a bitline equivalent circuit and a pre-charging circuit in accordance with one embodiment of the present invention; and

FIG. 3 illustrates a method for pre-charging a memory device bitline in accordance with one embodiment of the present invention.

For clarity, previously defined features retain their reference numerals in subsequent drawings.

### DETAILED DESCRIPTION OF ILLUSTRATIVE EMBODIMENTS

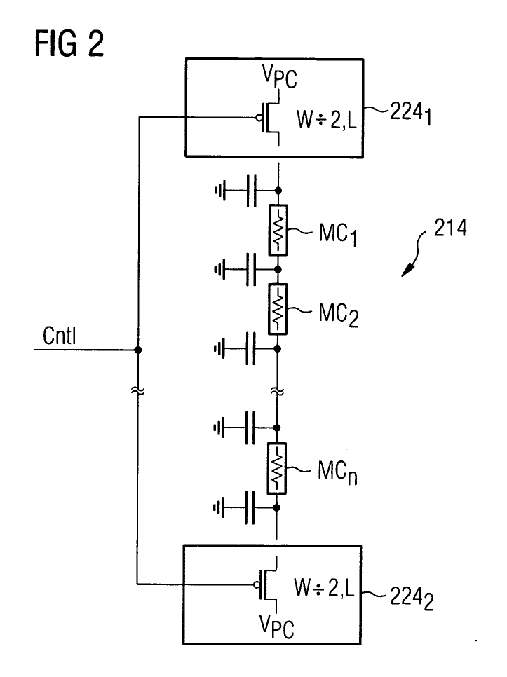

FIG. 2 illustrates a portion of a memory device showing a bitline equivalent circuit and a pre-charging circuit in accordance with one embodiment of the present invention. The memory architecture includes a plurality of pre-charging circuits 224, which are distributed along the bitline 214, the pre-charging circuits 224 being substantially concurrently operable to apply the desired pre-charging voltage. By distributing the pre-charging circuits 224 along the bitline 214 (maximally spaced-apart in a particular embodiment) and controlling the circuits to apply the pre-charge voltage substantially concurrently, the effective delay by which the pre-charging voltage is applied to one or more of the memory cells coupled to the bitline is reduced.

In the exemplary embodiment of FIG. 2, the plurality of distributed pre-charging circuits include a first pre-charging circuit 224₁ located at a first end of the bitline equivalent circuit 214, and a second pre-charging circuit 224₂ located at a second end of the bitline equivalent circuit 214. In this embodiment, the effective delay by which a pre-charge voltage develops on memory cells MCₙ₋₂, MCₙ₋₁ and MCₙ is significantly reduced, as the second pre-charging circuit 224₂ provides the pre-charging voltage to these cells with minimal delay. Memory cell MC_{n/2} located halfway between the first and second pre-charging circuit 224₁ and 224₂ represents the memory cell having the longest pre-charge voltage delay, as the pre-charging voltage supplied by both pre-charging circuits 224₁ and 224₂ will reach this memory cell with substantially the same delay. However, the longest delay time in this embodiment is only one-half that of the single pre-charging circuit embodiment in which the longest delay time occurs at the nth memory cell, and accordingly, the timing allocated to the pre-charging operation can be reduced by one-half. Of course, additional pre-charging circuits can be added to further reduce the pre-charge voltage delay, as the effective longest path between pre-charging circuits will be reduced with the addition of further pre-charging circuits. As noted above, the pre-charging circuits can be distributed, so as to be maximally spaced-away from each other along the bitline.

In one embodiment as shown, each of the pre-charging circuits 224 includes a PMOS transistor having a source coupled to a pre-charging voltage V_{PC}, which is to be applied to the bitline 214, a drain terminal coupled to the bitline 214, and a gate terminal coupled to receive a pre-charge control signal Cntl. The pre-charge control signal Cntl may be supplied via a signal divider, or similar structure, which provides substantially the same delay to each of the gate terminals, such that all of the pre-charge circuits 224 are activated substantially concurrently. The memory cells MC₁₋ₙ may comprise non-volatile or volatile structures of various technologies, for example, EEPROM, FLASH, magnetic random access memory (MRAM), phase change memory (PCM), as well as other memory cells that employ line pre-charging.

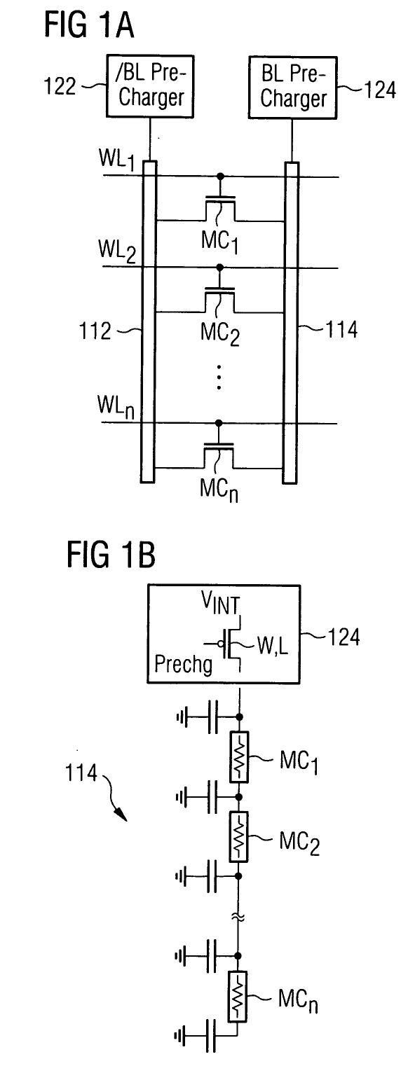

Further illustrated in FIG. 2 is a feature of the invention whereby the loading of the pre-charging circuit is distributed. Whereas in the conventional device, the pre-charging circuit's loading, primarily defined by the transistor's gate periphery, is located at one point along the bitline, the pre-charging circuit's loading in the present invention is distributed along the bitline 214. As shown in FIG. 2, pre-charging circuits 224₁ and 224₂ employ transistors that are approximately one-half the gate periphery of the transistor(s) used in the single pre-charging circuit 124 in FIG. 1B. In another embodiment of the present invention in which a greater number of transistor-based pre-charging circuits are employed, each circuit would implement smaller gate periphery transistors, the collective gate periphery of which would approach the total gate periphery of the single pre-charging circuit 124 employed in the conventional device. Of course, a transistor's gate periphery is only one loading parameter for which the aforementioned distributed process may apply. Other parameters, such as inductance, capacitance, etc., may also be included within the distributed pre-charging circuits.

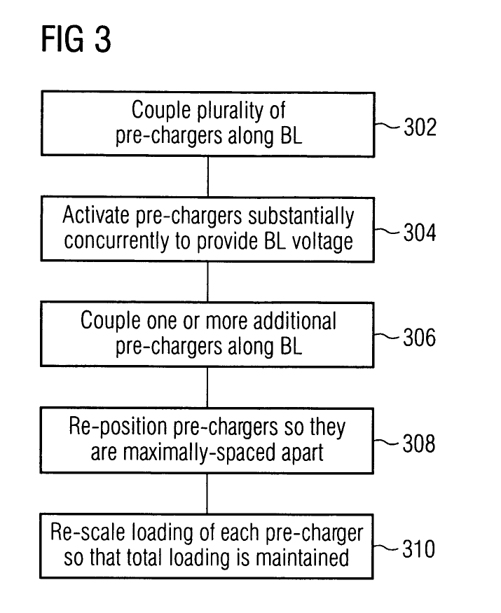

FIG. 3 illustrates a method for pre-charging a memory device bitline in accordance with one embodiment of the present invention. At 302, a plurality of pre-charging circuits are coupled to a bitline in a memory. In a particular embodiment of this process, the plurality of pre-charging circuits are coupled to the memory bitline such that the pre-charging circuits are maximally-spaced apart from one another. A particular embodiment of this process is one in which two pre-charging circuits are used, one at opposite ends of the bitline. In another embodiment in which three or more pre-charging circuits are used, the pre-charging circuits are evenly spaced apart along the bitline.

At 304, the plurality of pre-charging circuits are activated substantially concurrently to apply the pre-charge voltage to the bitline. This process may be performed by supplying a common pre-charge control signal Cntl to the input of a power divider (having two or more outputs), the power divider imparting substantially the same signal delay to all of its output signals. In this manner, all of the pre-charging circuits will receive (a divided portion of) the Cntl signal substantially concurrently, resulting in the concurrent activation of the pre-charging circuits.

Optionally, the method may include coupling one or more further pre-charging circuits to the bitline. In such an embodiment, the method at 306 includes coupling the additional one or more pre-charging circuits to the memory device's bitline, and repositioning the plurality of pre-charging circuits along the bitline, such that all of the pre-charging circuits are maximally-spaced apart (308). Also at 310, the loading of each pre-charging circuit is re-scaled, such that the total loading of all the pre-charging circuits is substantially the same as the previous loading. For example, when a new pre-charging circuit 224₃ (not shown) is added to the bitline, the gate periphery of each pre-charging circuit is re-scaled so as to provide one third of the total gate periphery allocated to the bitline. In this manner, the bitline's total loading is maintained.

As readily appreciated by those skilled in the art, the described processes may be implemented in hardware, software, firmware, or a combination of these implementations as appropriate. In addition, some or all of the described processes may be implemented as computer readable instruction code resident on a computer readable medium (removable disk, volatile or non-volatile memory, embedded processors, etc.), the instruction code operable to program a computer of other such programmable device to carry out the intended functions.

The foregoing description has been presented for purposes of illustration and description. It is not intended to be exhaustive or to limit the invention to the precise form disclosed, and obviously many modifications and variations are possible in light of the disclosed teaching. The described embodiments were chosen in order to best explain the principles of the invention and its practical application to thereby enable others skilled in the art to best utilize the invention in various embodiments and with various modifications as are suited to the particular use contemplated. It is intended that the scope of the invention be defined by the claims appended hereto.

What is claimed is:

1. A memory device, comprising:
a plurality of memory cells coupled to a bitline; and
a plurality of pre-charging circuits coupled to the bitline, wherein each of the pre-charging circuits is operable to supply a pre-charge voltage to the bitline.

2. The memory device of claim 1, wherein the plurality of pre-charging circuits are maximally-spaced apart along the bitline.

3. The memory device of claim 1, wherein the plurality of pre-charging circuits comprises a first pre-charging circuit coupled at a first end of the bitline, and a second pre-charging circuit coupled to a second end of the bitline.

4. The memory device of claim 1, wherein each of the pre-charging circuits comprises one or more transistors having substantially a same gate periphery, wherein a collective gate periphery of all of the pre-charging circuits defines a predefined total gate periphery.

5. The memory device of claim 1, wherein the plurality of memory cells comprise non-volatile memory cells.

6. The memory device of claim 1, wherein the plurality of memory cells comprise volatile memory cells.

7. In a memory device having a plurality of memory cells coupled to a bitline, a method for pre-charging the bitline to a predefined voltage, the method comprising:
coupling a plurality of pre-charging circuits to the bitline; and
activating each of the plurality of pre-charging circuits substantially concurrently to provide the predefined voltage to the bitline.

8. The method of claim 7, wherein coupling the plurality of pre-charging circuits comprises coupling the pre-charging circuits to the bitline in locations, whereby the pre-charging circuits are maximally-spaced apart.

9. The method of claim 7, wherein coupling the plurality of pre-charging circuits comprises coupling a first pre-charging circuit to a first end of the bitline, and a second pre-charging circuit to a second end of the bitline.

10. The method of claim 7, wherein each of the pre-charging circuits comprises one or more transistors having substantially a same gate periphery, wherein a collective gate periphery of all of the pre-charging circuits defines a predefined total gate periphery.

11. The method of claim 10, further comprising:
coupling a further pre-charging circuit to the bitline;
re-positioning the plurality of pre-charging circuits along the bitline, such that all of the pre-charging circuits are maximally-spaced apart; and
re-scaling loading of each pre-charging circuit, such that a collective loading of all pre-charging circuits is substantially equivalent to a predefined bitline total loading.

12. The method of claim 11, wherein re-scaling comprises re-scaling the gate periphery of each pre-charging circuit.

13. A memory device, comprising:
a plurality of memory cells coupled to a bitline;
a first pre-charging circuit coupled to a first end of the bitline; and
a second pre-charging circuit coupled to a second end of the bitline, wherein the first and second pre-charging circuits are each operable to supply a pre-charge voltage to the bitline.

14. The memory device of claim 13, wherein each of the pre-charging circuits comprises one or more transistors having substantially a same gate periphery.

15. The memory device of claim 13, wherein the plurality of memory cells comprise non-volatile memory cells.

16. The memory device of claim 13, wherein the plurality of memory cells comprise volatile memory cells.

17. A memory device, comprising:
a plurality of memory cells coupled to a bitline; and
a plurality of pre-charging circuits coupled to the bitline, wherein each of the pre-charging circuits is operable to supply a pre-charge voltage to the bitline, wherein the plurality of pre-charging circuits are maximally-spaced apart along the bitline, and wherein each of the pre-charging circuits comprises one or more transistors having substantially the same gate periphery.

18. The memory device of claim 17, wherein the plurality of pre-charging circuits comprise a first pre-charging circuit coupled to a first end of the bitline, and a second pre-charging circuit coupled to a second end of the bitline.

19. The memory device of claim 17, wherein the collective gate periphery of all of the pre-charging circuits defines a predefined total gate periphery.

20. The memory device of claim 17, wherein the plurality of memory cells comprise non-volatile memory cells.

21. The memory device of claim 17, wherein the plurality of memory cells comprise volatile memory cells.

22. A memory device, comprising:
a bitline;
a plurality of memory cells coupled to the bitline; and
means for pre-charging coupled to at least two spaced-apart portions of the bitline, wherein the means for pre-charging is operable to supply a pre-charge voltage to the bitline.
